(19) United States
(12) Patent Application Publication
(10) Pub. No.: US 2026/0030403 A1
(43) Pub. Date: Jan. 29, 2026

(54) STRATUM REINFORCEMENT MODELING AND ANALYSIS METHOD FOR SHIELD TUNNEL CROSSING EXISTING STRUCTURE

(71) Applicants: Zhejiang University, Hangzhou (CN); Hangzhou Metro Group Co., Ltd., Hangzhou (CN); China Railway First Group Urban Track Transport Engineering Co., Ltd., Wuxi (CN)

(72) Inventors: Xiaowei YE, Hangzhou (CN); Hongxiang CHEN, Hangzhou (CN); Jianshe QIN, Hangzhou (CN); Jundong MU, Hangzhou (CN); Zhilin SONG, Hangzhou (CN); Ping WANG, Hangzhou (CN); Yonghui WANG, Hangzhou (CN); Yanbo CHEN, Hangzhou (CN)

(21) Appl. No.: 19/344,299

(22) Filed: Sep. 29, 2025

(30) Foreign Application Priority Data
May 30, 2025 (CN) 202510714001.0

(51) Int. Cl. G06F 30/17; G06T 17/05; G06T 17/20

(52) U.S. Cl. CPC G06F 30/17; G06T 17/05; G06T 17/20

(57) ABSTRACT

A stratum reinforcement modeling and analysis method for a shield tunnel crossing an existing structure is provided. Geological information and an engineering structure condition of the existing structure are acquired. Physical parameters of different soil mass layers are determined based on a laboratory test. A three-dimensional (3D) model is constructed. Mesh generation is performed on the 3D model defining a constraint for the 3D model. Model parameters are selected for the 3D model. A soil mass constitutive model is selected for the 3D model. Synchronous grouting simulation, construction load simulation and shield tunneling construction simulation are performed on the 3D model. Stratum parameters are changed to achieve stratum reinforcement modeling. Data analysis is performed by adopting different reinforcement schemes to achieve stratum reinforcement modeling and numerical analysis of the process of the shield tunnel crossing the existing structure.

### CROSS-REFERENCE TO RELATED APPLICATIONS

This application claims the benefit of priority from Chinese Patent Application No. 202510714001.0, filed on May 30, 2025. The content of the aforementioned application, including any intervening amendments made thereto, is incorporated herein by reference in its entirety.

### TECHNICAL FIELD

This application relates to shield tunneling engineering, and more particularly to a stratum reinforcement modeling and analysis method for a shield tunnel crossing an existing structure.

### BACKGROUND

With the rapid development of urban rail transit construction, subway networks have become increasingly dense. The process of new tunnel lines crossing existing structures of old lines is an issue that must be addressed in future subway construction. During the process of a shield tunnel crossing the existing structures, conventional underground crossing construction typically adopts the following techniques. Vertical shafts are excavated on the ground, followed by employing horizontal freezing technology and grouting reinforcement techniques within the shafts to improve the soil layer at the station foundation. Finally, manual tunneling is implemented by using a mining method. This construction approach involves high costs, long project cycles and significant safety risks. If the method of the shield tunnel directly crossing existing structures is adopted, it can effectively shorten the construction period, reduce costs, enhance engineering safety, and deliver significant economic and social benefits. Meanwhile, the process of the shield tunnel crossing existing structures increases the difficulty of shield tunnel construction and raises the requirements for stratum reinforcement and the protection of existing structures.

### SUMMARY

In view of the above problems in the prior art, the disclosure provides a stratum reinforcement modeling and analysis method for a shield tunnel crossing an existing structure. The core idea involves developing a numerical simulation approach for stratum reinforcement based on mechanical mechanisms. This method provides a pathway to investigate influence patterns of different reinforcement schemes on controlling underground passage settlement and improving the deformation and stress characteristics of existing structures, thereby determining reasonable reinforcement ranges. This can address the challenge of selecting appropriate stratum reinforcement and protection methods for a shield tunnel crossing an existing structure, so that the numerical model is more aligned with actual construction requirements.

Technical solutions of the present disclosure are described as follows.

This application provides a stratum reinforcement modeling and analysis method for a shield tunnel crossing an existing structure, comprising:
(S1) acquiring geological information and an engineering structure condition of the existing structure through geological survey, and determining physical parameters of different soil mass layers based on a laboratory test;
(S2) constructing a three-dimensional (3D) model, performing mesh generation on the 3D model, and defining a constraint for the 3D model, wherein the 3D model comprises an overall stratum model of a shield tunneling area and an internal model combining an existing structure model with a shield tunnel model;
(S3) selecting model parameters for the 3D model;
(S4) selecting a soil mass constitutive model for the 3D model;
(S5) performing synchronous grouting simulation on the 3D model;
(S6) performing simulation of a construction load on the 3D model;
(S7) performing simulation of a shield tunneling construction process on the 3D model; and
(S8) changing stratum parameters to achieve stratum reinforcement modeling of a process of the shield tunnel crossing the existing structure, and performing data analysis by adopting different reinforcement schemes to achieve stratum reinforcement modeling and numerical analysis of the process of the shield tunnel crossing the existing structure.

In some embodiments, step (S1) is performed through steps of:
(S11) performing stratum thickness division based on a geological prospecting borehole coring condition and engineering information of the existing structure, and acquiring stratum distribution information and an internal structure condition of a construction area; and
(S12) acquiring the physical parameters through the laboratory test, and simulating mechanical behavior of a soil mass in the construction area; wherein the physical parameters comprise unit weight, water content, void ratio, cohesion, internal friction angle and elastic modulus of the soil mass.

In some embodiments, step (S2) is performed through steps of:
(S21) constructing and generating the overall stratum model based on the geological information and the engineering structure condition, and performing stratum boundary division and naming;
(S22) constructing the existing structure model based on actual design drawing dimensions;
(S23) constructing the shield tunnel model, wherein the shield tunnel model comprises a segment lining, a grouting layer and a shield shell; and constructing the 3D model by integrating the overall stratum model, the existing structure model and the shield tunnel model according to an actual construction scheme; and
(S24) performing mesh generation on the 3D model, wherein each of a soil mass, the segment lining, the grouting layer, the existing structure and the shield shell adopts an eight-node hexahedral mesh element; and
defining the constraint for the 3D model, wherein a bottom of the 3D model adopts a vertical constraint, a periphery of the 3D model adopts a horizontal constraint, and a top of the 3D model is a free boundary.

In some embodiments, step (S3) is performed through steps of:
according to an influence of a lining joint on stiffness of a lining structure, reducing a stiffness of a segment lining with a stiffness reduction coefficient of 0.6; and determining values of physical and mechanical parameters of a grouting layer, a shield shell, the segment lining, an underground passage and the existing structure based on the geological information and the engineering structure condition; wherein the physical and mechanical parameters comprise density, elastic modulus and Poisson's ratio.

In some embodiments, step (S4) is performed through steps of:
selecting a Modified Cam-Clay model as the soil mass constitutive model based on the geological information and the engineering structure condition, wherein the Modified Cam-Clay model is expressed as:

$${( \frac{t}{{M}_{a}} )}^{2} + \frac{1}{{β}^{2}} {( \frac{P}{a} - 1 )}^{2} = 1 ,$$

wherein M is a slope of a critical state line (CSL) on a P−t plane, and is called a critical state stress ratio, α is a value of P corresponding to an intersection point between an ellipse and the CSL, β is a parameter controlling a shape of a yield surface, a value of β is equal to 1 on a first side where P<α, and is free of being restricted to 1 on a second side where P>α, the value of β serves to affect the shape of the yield surface on a corresponding one of the first side and the second side, t is a generalized shear stress, and P is an effective mean principal stress;
assigning values to soil mass parameters of the Modified Cam-Clay model based on the geological information and the engineering structure conditions, wherein the soil mass parameters comprise density, critical state stress ratio, slope of a normal consolidation curve, slope of a rebound curve, Poisson's ratio and at-rest earth pressure coefficient of a soil mass.

In some embodiments, step (S5) is performed through steps of:
generalizing grouting as an equivalent layer that is homogeneous, equal-thickness and elastic based on the geological information and the engineering structure condition, wherein a thickness δ of the equivalent layer is calculated through the following equation:

$$δ = η Δ ,$$

wherein Δ is a theoretical value of a shield tail void, and η is a reduction coefficient ranging from 0.7 to 2.0.

In some embodiments, the construction load comprises a tunneling face support pressure and a shield tail grouting pressure; and
step (S6) is performed through steps of:
determining the tunneling face support pressure according to an actual tunneling face support pressure recorded during shield tunneling in an actual project; determining the shield tail grouting pressure by back-calculation of an actual shield tail grouting pressure from an instrument-recorded grouting pressure through the following equation:

$${P}_{g} = {P}_{g 0} - Δ {P}_{1} - Δ {P}_{2} - Δ {P}_{3} ,$$

wherein P_{g} is the instrument-recorded grouting pressure, P_{g0} is the actual shield tail grouting pressure, ΔP₁ is a frictional pressure loss, ΔP₂ is a local pressure loss, and ΔP₃ is a grouting pressure loss during vertical distribution expansion; and ΔP₁, ΔP₂ and ΔP₃ are determined based on hydrodynamic calculation.

In some embodiments, step (S7) is performed through steps of:
performing step-by-step tunneling simulation on the shield tunneling construction process using an element birth and death method provided by an ABAQUS software, and discretizing a continuous steady-state process of shield tunneling construction into a stepwise steady-state tunneling process with a length of one tunneling step equal to a distance of three lining rings in the shield tunnel model; wherein each tunneling step comprises a shield tunneling step, the process of the shield tunnel crossing the existing structure and a shield tail detachment process; and
during the shield tunneling step, killing a corresponding soil mass element, and simultaneously activating a segment lining, a grouting, a preset shield shell element and a load condition at a corresponding position; during simulation of the process of the shield tunnel crossing the existing structure, killing a conflicting part of the existing structure that the shield tunnel crosses by using the element birth and death method, and activating the preset shield shell element; and after a shield tail is detached, killing the preset shield shell element, and activating a preset shield shell element grouting layer, a segment lining layer and a corresponding grouting pressure.

In some embodiments, step (S8) is performed through steps of:
simulating reinforcement measures by changing parameters relevant to a stratum material based on the 3D model, constructing a stratum reinforcement numerical model using an ABAQUS finite element software; and adopting an elastic constitutive model for a reinforced soil material, wherein parameters of the reinforced soil material comprises density, Poisson's ratio and elastic modulus of a soil mass; and
acquiring response curves of different reinforcement schemes for controlling settlement of an underground passage and improving deformation and stress characteristics of the existing structure using the Abaqus finite element software, determining a reasonable reinforcement range, and evaluating a stratum reinforcement protection effect.

Compared to the prior art, the present disclosure has the following beneficial effects.

Compared to traditional stratum reinforcement assessment methods, the method of the present disclosure more intuitively visualizes the construction simulation of tunnel boring machines crossing existing structures, resulting in higher efficiency in result acquisition, more accurate results and lower costs. This application provides an approach to investigating effects of different reinforcement schemes on settlement control and construction-induced deformation mitigation from the perspective of numerical simulation, which holds significant theoretical and practical engineering value for the settlement control and protection of upper structures. This serves as a reference for determining a rational reinforcement range for the tunnel boring machines crossing the existing structures and for evaluating the protective effect of stratum reinforcement, thereby providing theoretical guidance for related engineering reinforcement technologies.

### BRIEF DESCRIPTION OF THE DRAWINGS

The patent or application file contains at least one drawing executed in color. Copies of this patent or patent application publication with color drawing(s) will be provided by the Office upon request and payment of the necessary fee.

FIG. 1 is a flow chart of numerical simulation steps in accordance with an embodiment of the present disclosure;

FIG. 2 schematically illustrates pile-tunnel positional relationship and form of pile foundation intrusion into a tunnel section in accordance with an embodiment of the present disclosure;

FIG. 3a is a schematic diagram of an overall stratum model in accordance with an embodiment of the present disclosure;

FIG. 3b is a schematic diagram of an internal model of a combination of an existing structure model and a shield tunnel model in accordance with an embodiment of the present disclosure;

FIG. 4a is a schematic diagram of shield tail grouting in accordance with an embodiment of the present disclosure;

FIG. 4b is a schematic diagram of an equivalent layer in accordance with an embodiment of the present disclosure;

FIGS. 5a-e schematically illustrate shield construction process simulation from step n to step n+4, respectively, in accordance with an embodiment of the present disclosure;

FIG. 6 schematically illustrates positional relationship model among an existing structure, a tunnel and a reinforcement area in accordance with an embodiment of the present disclosure;

FIGS. 7a-d are schematic diagrams of four reinforcement schemes in Reinforcement Scheme 1 in accordance with an embodiment of the present disclosure, where soil mass reinforcement under a passage is maintained at 3 m, a horizontal reinforcement range of a pile grinding area is maintained at 3 m outside an engineering pile, and soil masses within 1 m, 2 m, 3 m and 4 m above and below the tunnel in the pile grinding area are reinforced, respectively;

FIG. 7e is a schematic diagram of a horizontal reinforcement range under a passage base slab in Reinforcement Scheme 1;

FIG. 7f is a schematic diagram of the horizontal reinforcement range of the pile grinding area in Reinforcement Scheme 1;

FIGS. 8a-d are schematic diagrams of four reinforcement schemes in Reinforcement Scheme 2 in accordance with an embodiment of the present disclosure, where soil mass reinforcement above and below a tunnel is maintained at 3 m, a horizontal reinforcement range of a pile grinding area is maintained at 3 m outside an engineering pile, and soil masses within 1 m, 2 m, 3 m and 4 m under an underground passage are reinforced, respectively;

FIG. 8e is a schematic diagram of a horizontal reinforcement range under a passage base slab in Reinforcement Scheme 2;

FIG. 8f is a schematic diagram of the horizontal reinforcement range of the pile grinding area in Reinforcement Scheme 2;

FIGS. 9a-d are schematic diagrams of four reinforcement schemes in Reinforcement Scheme 3 in accordance with an embodiment of the present disclosure, where soil mass reinforcement under a passage is maintained at 3 m, soil mass reinforcement above and below a tunnel is maintained at 3 m, and soil masses within 0.7 m, 2 m, 3 m and 4 m outside an engineering pile are reinforced, respectively;

FIG. 9e is a schematic diagram of a horizontal reinforcement range under a passage base slab in Reinforcement Scheme 3;

FIG. 9f is a schematic diagram of a vertical reinforcement range in Reinforcement Scheme 3;

FIG. 10 shows comparison of overall passage settlement with different vertical reinforcement thicknesses of the soil mass in the pile grinding area in Reinforcement Scheme 1;

FIG. 11a shows comparison of maximum lateral deformation of pile foundation during a right-line tunneling process under different reinforcement manners in Reinforcement Scheme 1;

FIG. 11b shows comparison of maximum lateral deformation of pile foundation during a left-line tunneling process under different reinforcement manners in Reinforcement Scheme 1;

FIGS. 12a-d show comparison of maximum principal stress of a pile foundation after tunnel construction is completed under 1a-1d reinforcement manners in Reinforcement Scheme 1;

FIG. 13a-c show comparison of maximum principal stress of pile foundations in zones A, B and C, respectively, after the tunnel construction is completed under different reinforcement manners in Reinforcement Scheme 1;

FIG. 14 shows comparison of overall passage settlement with different vertical reinforcement thicknesses under the passage base slab in Reinforcement Scheme 2;

FIG. 15a shows comparison of maximum lateral deformation of pile foundation during a right-line tunneling process under different reinforcement manners in Reinforcement Scheme 2;

FIG. 15b shows comparison of maximum lateral deformation of pile foundation during a left-line tunneling process under different reinforcement manners in Reinforcement Scheme 2;

FIGS. 16a-d show comparison of maximum principal stress of a pile foundation after tunnel construction is completed under 2a-2d reinforcement manners in Reinforcement Scheme 2 in accordance with an embodiment of the present disclosure;

FIG. 17 show comparison of overall passage settlement with different longitudinal reinforcement thicknesses of the soil mass in the pile grinding area in Reinforcement Scheme 3;

FIG. 18a shows comparison of maximum lateral deformation of pile foundation during a right-line tunneling process under different reinforcement manners in Reinforcement Scheme 3;

FIG. 18b shows comparison of maximum lateral deformation of the pile foundation during a left-line tunneling process under different reinforcement manners in Reinforcement Scheme 3; and

FIGS. 19a-c show comparison of maximum principal stress of pile foundations in zones A, B and C, respectively, after the tunnel construction is completed under different reinforcement manners in Reinforcement Scheme 3.

### DETAILED DESCRIPTION OF EMBODIMENTS

The present disclosure will be further described below in conjunction with the accompanying drawings and embodiments.

### Embodiment 1

A construction section of pile foundation engineering where a certain section of Shaoxing Metro crosses an underground pedestrian crossing is selected, and simulation is carried out using a finite element software ABAQUS.

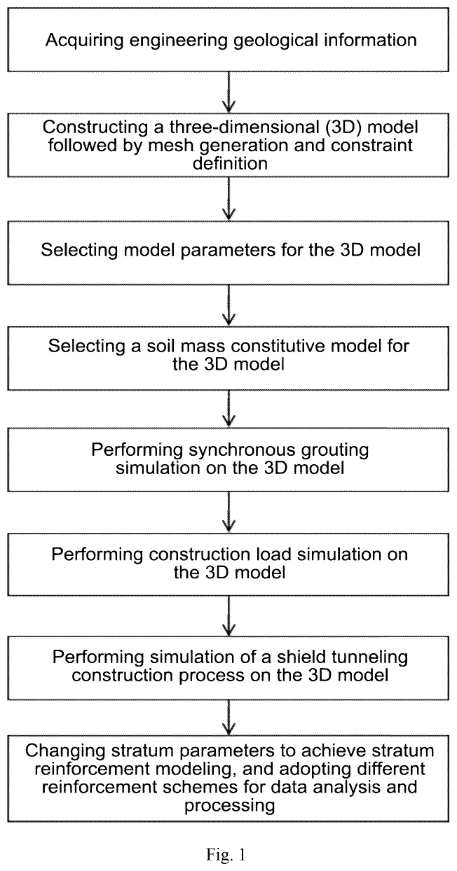

Provided herein is a numerical simulation method for shield cutter cutting through a reinforced concrete diaphragm wall. As shown in FIG. 1, the numerical simulation method includes the following steps.
Step (S1) Geological information and an engineering structure condition of the existing structure are acquired through geological survey. Physical parameters of different soil mass layers are determined based on a laboratory test.
Step (S2) A three-dimensional (3D) model is constructed, including an overall stratum model of a shield tunneling area and an internal model combining an existing structure model with a shield tunnel model. Mesh generation is performed on the 3D model, and constraints are defined for the 3D model.
Step (S3) Model parameters of the 3D model are selected.
Step (S4) A soil mass constitutive model is selected for the 3D model.
Step (S5) Synchronous grouting simulation is performed on the 3D model.
Step (S6) Construction load simulation is performed on the 3D model.
Step (S7) Shield tunneling construction simulation is performed on the 3D model.
Step (S8) Stratum parameters are changed to achieve stratum reinforcement modeling of a process of the shield tunnel crossing the existing structure. Data analysis is performed by adopting different reinforcement schemes to achieve stratum reinforcement modeling and numerical analysis of the process of the shield tunnel crossing the existing structure.

The step (S1) is performed through the following steps. Based on a geological prospecting borehole coring condition and engineering information of the existing structure, stratum thickness division is performed, and stratum distribution information and an internal structural situation of a construction area are acquired. Physical parameters of different soil mass layers are determined according to a laboratory test, and a mechanical behavior of a soil mass in the construction area is simulated, enabling the numerical simulation results to better guide field construction. The physical parameters of the soil mass are shown in Table 1.

TABLE 1
Physical parameters of soil mass

| | | | | | | | | Internal | |
|---|---|---|---|---|---|---|---|---|---|
| | Soil | Unit | Water | Liquid | Plastic | | | friction | Elastic |
| | layer | weight | content | limit | limit | Void | Cohesion | angle | modulus |
| Layer No. | name | (kN/m³) | (%) | (%) | (%) | ratio | (kPa) | (°) | (MPa) |
| \textcircled{1}₂ | Plain | 18.5 | 31.1 | 37.4 | 22.9 | 0.90 | 21.3 | 15.6 | 4.73 |
| | filled | | | | | | | | |
| | soil | | | | | | | | |
| \textcircled{2}₂₋₄ | Clayey | 18.7 | 30.6 | — | — | 0.85 | 16.2 | 24.6 | 8.81 |
| | silt | | | | | | | | |
| \textcircled{3}₁₋₂ | Mucky | 16.9 | 49.0 | 44.9 | 26.1 | 1.37 | 13.5 | 9.7 | 2.86 |
| | clay | | | | | | | | |
| \textcircled{4}₁ | Silty | 19.0 | 31.9 | 33.8 | 21.3 | 0.83 | 32.8 | 13.5 | 4.8 |
| | clay | | | | | | | | |
| \textcircled{4}₂ | Silty | 19.4 | 26.7 | 38.1 | 23.1 | 0.76 | 56.2 | 17.9 | 5.94 |
| | clay | | | | | | | | |
| \textcircled{4}₃ | Silty | 18.5 | 31.4 | 36.5 | 22.2 | 0.90 | 28.1 | 18.6 | 5.49 |
| | clay | | | | | | | | |
| | with | | | | | | | | |
| | silt | | | | | | | | |
| \textcircled{5}₁ | Mucky | 17.6 | 40.9 | 38.3 | 23.3 | 1.15 | 13.9 | 11.1 | 3.48 |
| | silty | | | | | | | | |
| | clay | | | | | | | | |
| \textcircled{5}₂ | Silty | 18.2 | 37.3 | 39.1 | 23.4 | 1.04 | 21.0 | 13.0 | 3.95 |
| | clay | | | | | | | | |
| \textcircled{6}₁ | Silty | 18.0 | 38.2 | 44.4 | 26.3 | 1.04 | 32.3 | 15.1 | 4.99 |
| | clay | | | | | | | | |
| \textcircled{7}₂ | Silty | 18.3 | 38.2 | 41.3 | 24.5 | 1.07 | 20.1 | 12.5 | 3.78 |
| | clay | | | | | | | | |

(Note:
The subscript in the layer number represents different sublayers contained within the main soil layer.)

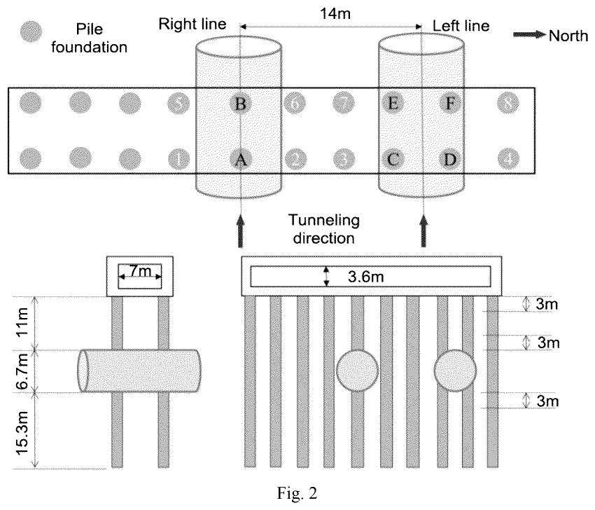

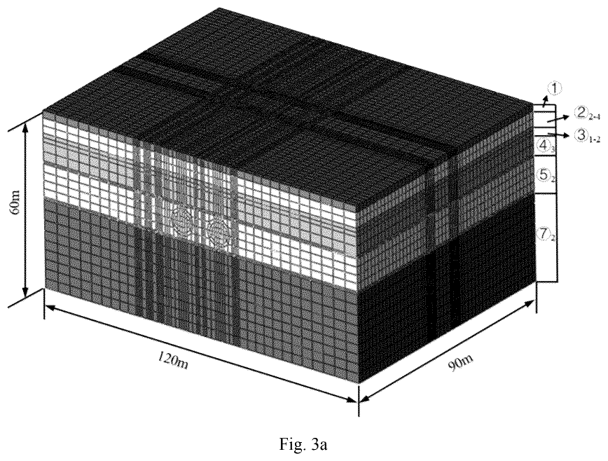

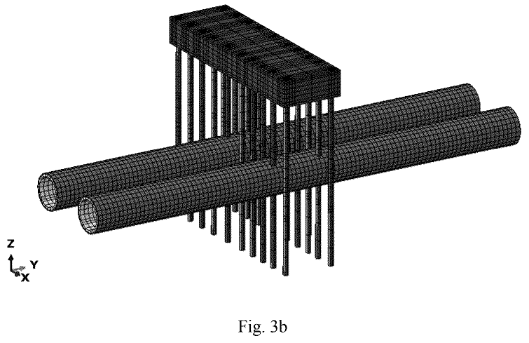

The step (S2) is performed through the following steps. An overall stratum model of the shield tunneling area is constructed. Considering all the underground passage pile foundations for this project would complicate the model and reduce computational efficiency. Therefore, the existing structure model and the shield tunnel model are constructed only based on engineering piles and the main structure of the passage within a tunnel influence zone. The pile-tunnel positional relationship and the form of pile foundation intrusion into a tunnel section, are shown in FIG. 2. The right and left lines are preset shield tunneling routes. When tunneling the right and left lines, it is necessary to cut 2 engineering piles (piles A and B) and 4 engineering piles (piles C, D, E and F) of the east pedestrian passage, respectively. The established 3D finite element numerical model of shield-soil mass-pile foundation is shown in FIGS. 3a-b. The model dimensions are 90 m in length, 120 m in width and 60 m height. The shield tunnel has an outer diameter of 6.7 m, an inner diameter of 5.9 m and a segment thickness of 0.4 m. A burial depth of a shield tunnel vault is set at 20 m, and a spacing between the left and right lines and the center line of the shield tunnel section is 14 m. The soil mass, segment lining, grouting layer, pile foundation and shield shell in the model all adopt eight-node hexahedral elements. A bottom of the model is subjected to vertical constraint, surrounding sides of the model are subjected to horizontal constraint, and a top of the model is set as a free boundary. The grouting layer, lining and passage pile foundation are simulated using an elastic model, where plastic strain is neglected. The influence of groundwater is not considered.

The step (S3) is performed through the following steps. Based on the influence of lining joints on the stiffness of the lining structure, the stiffness of the segment lining in the 3D model is reduced, with a stiffness reduction coefficient of the segment lining of 0.6. According to actual engineering conditions, physical and mechanical parameter values of the grouting layer, shield shell, lining, underground passage and existing structure are selected. The relevant physical and mechanical parameters are shown in Table 2.

TABLE 2
Relevant physical and mechanical parameter values

| | | | Elastic | |
|---|---|---|---|---|
| | | Density ρ | modulus E | Poisson's |
| Name | | (g/cm³) | (MPa) | ratio ν |
| Lining | | 2.4 | 20700 | 0.2 |
| Shield shell | | 27 | 210000 | 0.2 |
| Grouting | Early grouting stage | 1.8 | 4.8 | 0.35 |
| layer | Grouting hardening stage | 1.8 | 20 | 0.2 |

| | | | |
|---|---|---|---|
| Underground passage | 2.4 | 29000 | 0.2 |
| Pile foundation | 2.4 | 30000 | 0.25 |

S4. According to the conditions of this project, a Modified Cam-Clay model is adopted. A yield criterion expression of the Modified Cam-Clay model is expressed as follows:

$${( \frac{t}{{M}_{a}} )}^{2} + \frac{1}{{β}^{2}} {( \frac{P}{a} - 1 )}^{2} = 1 .$$

In the above equation, M is a slope of a critical state line (CSL) on a P−t plane, which is called a critical state stress ratio; α is a value of P corresponding to an intersection point between an ellipse and the CSL; β is a parameter controlling a shape of a yield surface, a value of β is equal to 1 on a first side where P<α, and is free of being restricted to 1 on a second side where P>α, and the value of β serves to affect the shape of the yield surface on a corresponding one of the first side and the second side; t is a generalized shear stress; and P is an effective mean principal stress. Meanwhile, soil mass parameters for the Modified Cam-Clay model are assigned based on the actual engineering conditions. The soil mass parameters are shown in Table 3.

TABLE 3
Soil mass parameters

| | | | | | | | At-rest |
|---|---|---|---|---|---|---|---|
| | | | Critical | Slope of a | Slope of a | | earth |
| | Soil | Density | state | normal | rebound | | pressure |
| Layer | layer | ρ | stress | consolidation | curve | Poisson's | coefficient |
| No. | name | (g/cm³) | ratio M | curve λ | κ | ratio V | K₀ |
| \textcircled{1} | Plain | 1.85 | 0.8 | 0.0574 | 0.0046 | 0.34 | 0.52 |
| | filled | | | | | | |
| | soil | | | | | | |
| \textcircled{2}₂₋₄ | Silty | 1.87 | 1.1 | 0.0299 | 0.0037 | 0.32 | 0.50 |
| | clay | | | | | | |
| \textcircled{3}₁₋₂ | Clayey | 1.69 | 0.61 | 0.1127 | 0.0096 | 0.35 | 0.59 |
| | silt | | | | | | |
| \textcircled{4}₃ | Silty | 1.85 | 0.95 | 0.0451 | 0.0084 | 0.3 | 0.46 |
| | clay | | | | | | |
| | with | | | | | | |
| | silt | | | | | | |
| \textcircled{5}₂ | Silty | 1.82 | 0.84 | 0.0671 | 0.0095 | 0.35 | 0.56 |
| | clay | | | | | | |
| \textcircled{7}₂ | Silty | 1.83 | 1.01 | 0.0494 | 0.0076 | 0.31 | 0.56 |
| | clay | | | | | | |

The step (S6) is performed through the following steps. According to the conditions of this project, the grouting is generalized as a homogeneous, equal-thickness and elastic equivalent layer. A thickness of the grouting equivalent layer can be determined through the following equation:

$$δ = η Δ .$$

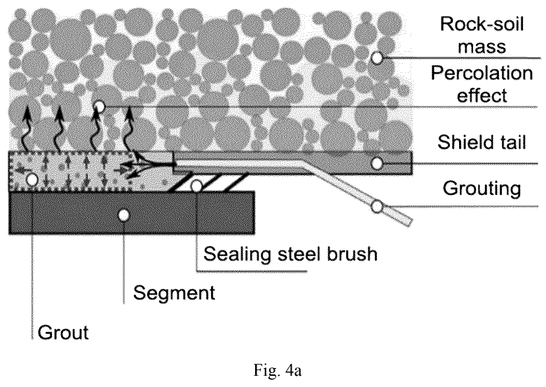

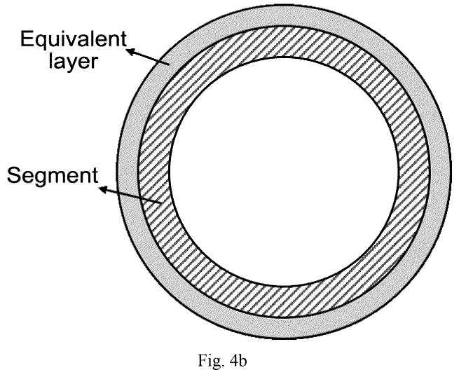

In the above equation, Δ is a theoretical value of a shield tail void, and η is a reduction coefficient ranging from 0.7 to 2.0. For this project, the thickness of the grouting equivalent layer is set as 20 cm. The tail grouting and the grouting equivalent layer are shown in FIGS. 4a-b.

Regarding step (S6), the construction load includes a tunneling face support pressure and a shield tail grouting pressure. The tunneling face support pressure is determined based on the actual tunneling face support pressure recorded by the shield in this project. A face thrust at an axis of the shield tunnel is set at 220 kN/m, considering a vertical gradient of 10 kPa/m. The shield tail grouting pressure is determined by back-calculating the actual shield tail grouting pressure from an instrument-recorded grouting pressure using the following equation:

$${P}_{g} = {P}_{g 0} - Δ {P}_{1} - Δ {P}_{2} - Δ {P}_{3} .$$

In the above equation, P_{g} is the instrument-recorded grouting pressure, P_{g0} is the actual shield tail grouting pressure, ΔP₁ is a frictional pressure loss taken as 30 kPa, ΔP₂ is a local pressure loss determined as 5 kPa based on hydrodynamic calculation, and ΔP₃ is a grouting pressure loss during vertical distribution expansion taken as 35 kPa.

According to the above equation, the grouting pressure at the axis of the shield tunnel is calculated to be 320 kPa, with a vertical gradient of 14 kPa/m taken into account.

The step (S7) is performed through the following steps. A step-by-step tunneling process of the shield construction is simulated using an element birth and death method provided by the ABAQUS software. A continuous steady-state process of shield construction is discretized into a stepwise steady-state tunneling process where a distance of three lining rings in the shield tunnel model is determined as one tunneling step. Each tunneling step includes a shield tunneling step, the process of the shield tunnel crossing the existing structure, and shield tail detachment.

During the shield tunneling step, corresponding soil mass elements are killed, while the segment lining, grouting, preset shield shell element and load condition at the corresponding locations are activated. When simulating the process of the shield tunnel crossing the existing structure, conflicting parts of the existing structure that the shield tunnel crosses are killed using the element birth and death method, and the preset shield shell element is activated. The preset shield shell element at the position where the shield tail detaches is killed, and the preset grouting layer, segment lining layer and corresponding grouting pressure of the preset shield shell element are activated.

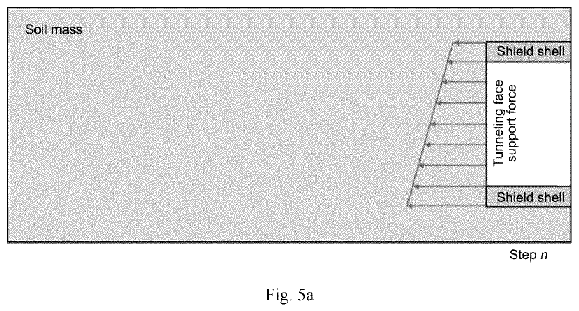

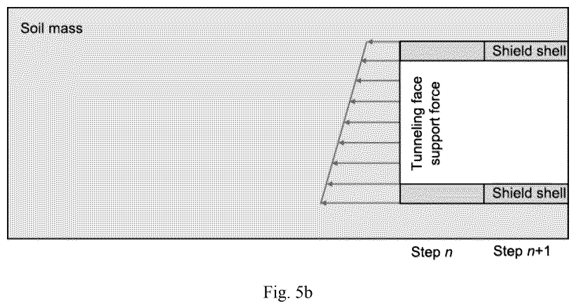

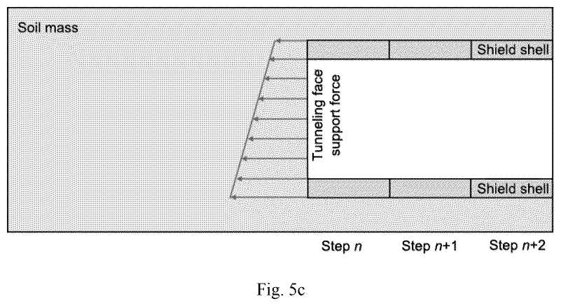

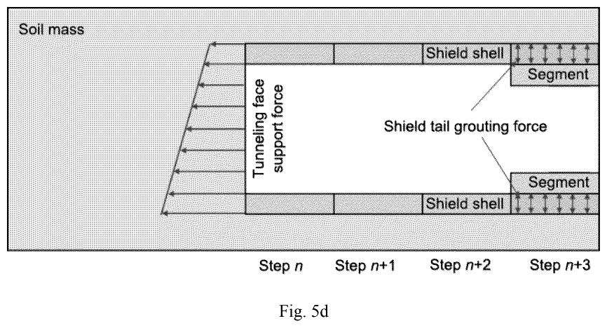

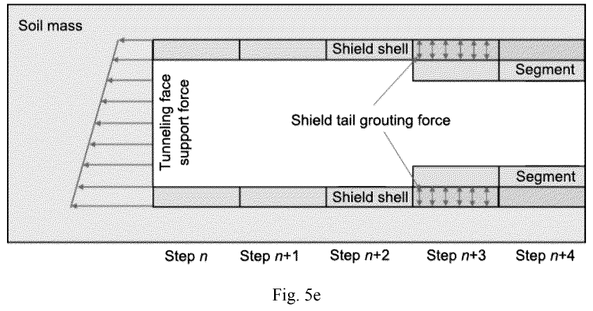

Schematic diagrams of the shield construction simulation from step n to step n+4 are shown in FIGS. 5a-e, respectively. The parameters relevant to step n to step n+4 are shown in Table 4.

TABLE 4
Parameters relevant to step n to step n + 4 of shield construction simulation

| Construction | | |
|---|---|---|
| step | Kill | Activate |
| Step n | Soil mass soilcut n | Shield shell Sₙ, face thrust Fₙ |
| Step n + 1 | Soil mass soilcut n + 1, face | Shield shell Sₙ₊₁, face thrust Fₙ₊₁ |
| | thrust Fₙ | |
| Step n + 2 | Soil mass soilcut n + 2, face | Shield shell Sₙ₊₂, face thrust Fₙ₊₂ |
| | thrust Fₙ₊₁ | |
| Step n + 3 | Soil mass soilcut n + 3, face | Shield shell Sₙ₊₃, face thrust Fₙ₊₃, lining |
| | thrust Fₙ₊₂, shield shell Sₙ | Lₙ, grouting layer Gₙ, grouting pressure Pₙ |
| Step n + 4 | Soil mass soilcut n + 4, face | Shield shell Sₙ₊₄, face thrust Fₙ₊₄, lining |
| | thrust Fₙ₊₃, shield shell Sₙ₊₁, | Lₙ₊₁, grouting layer Gₙ₊₁, grouting |
| | grouting pressure Pₙ | pressure Pₙ₊₁ |

The step (8) is performed through the following steps. Based on the 3D model, reinforcement measures are simulated by changing the relevant parameters of the stratum materials. A numerical model for stratum reinforcement is constructed using the ABAQUS finite element software. A reinforced soil material adopts an elastic constitutive model, and its relevant parameters include density, Poisson's ratio and elastic modulus of the soil mass. Response curves of different reinforcement schemes on controlling underground passage settlement and improving construction deformation and stress characteristics are acquired by using the ABAQUS finite element software instrument, so that a reasonable reinforcement range is determined, and the protective effect of stratum reinforcement is evaluated.

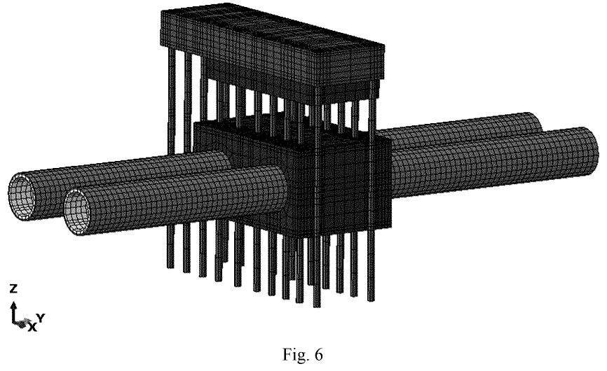

The numerical model for stratum reinforcement is constructed by using the ABAQUS finite element software. A reinforcement area is divided into a first area beneath a passage base slab and a second area where the shield grinds the pile. This serves to provide stable surrounding soil mass for shield pile grinding, prevent uneven settlement of the passage during the pile grinding process and after pile breakage, and avoid the risk of tensile cracking in the passage structure. The positional relationship among the existing structure, tunnel and reinforcement area is shown in FIG. 6. The presence or absence of reinforcement is realized in the numerical simulation by changing the stratum material parameters. The reinforced soil material adopts an elastic constitutive model, and parameters of the reinforced soil are shown in Table 5.

TABLE 5
Parameters of reinforced soil

| | | Elastic | |
|---|---|---|---|
| | Density ρ | modulus E | Poisson's |
| Name | (g/cm³) | (MPa) | ratio ν |
| Reinforced soil | 1.98 | 400 | 0.24 |

In order to obtain a reasonable reinforcement range, aiming to achieve the maximum protective effect with the minimum economic input while ensuring the safety of the existing structure, and based on the actual engineering situation, the protective effects of different reinforcement areas on the pile foundation are compared. Reinforcement schemes are set as follows, where reinforcement parameters are determined by using a Metro Jet System (MJS) reinforcement method.

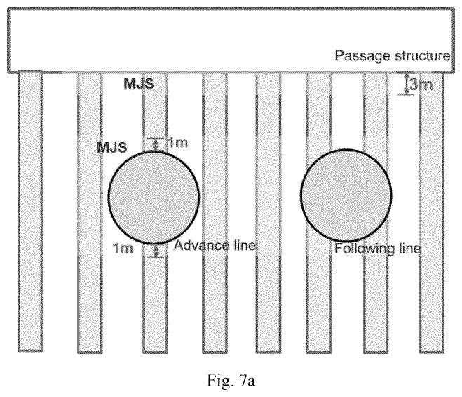

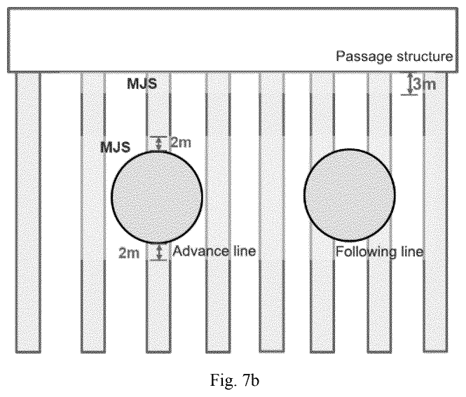

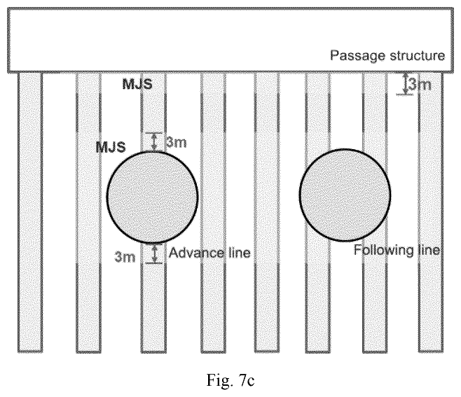

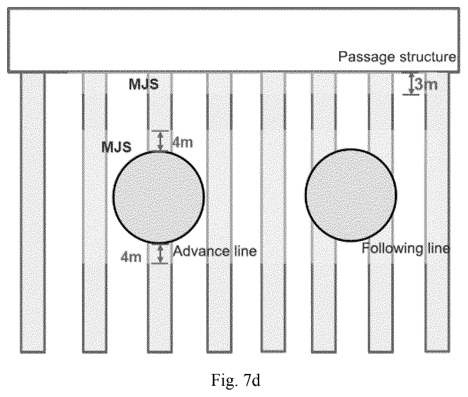

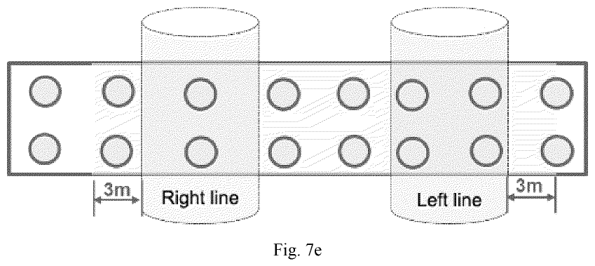

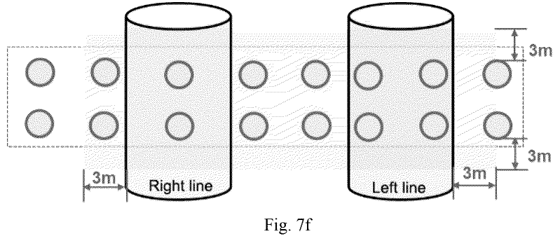

Reinforcement Scheme 1: The protective effects of different soil mass reinforcement thicknesses in the pile grinding area on the existing structure are compared to further investigate the reasonable vertical reinforcement thickness. With the soil mass reinforcement under the passage maintained at 3 m and the horizontal reinforcement range in the pile grinding area maintained at 3 m outside the engineering piles, as shown in FIGS. 7e-f, four reinforcement schemes are implemented by reinforcing the soil mass within ranges of 1 m (Scheme 1a), 2 m (Scheme 1b), 3 m (Scheme 1c), and 4 m (Scheme 1d) above and below the tunnel within the pile grinding area, respectively, as shown in FIGS. 7a-7d.

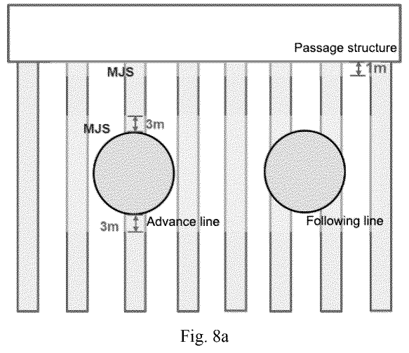

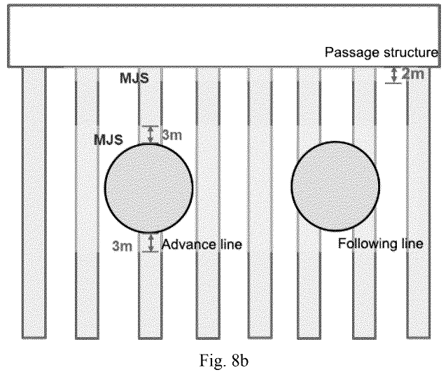

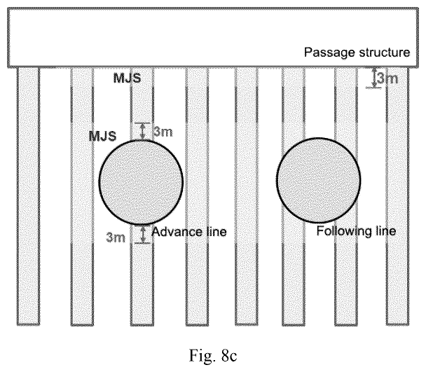

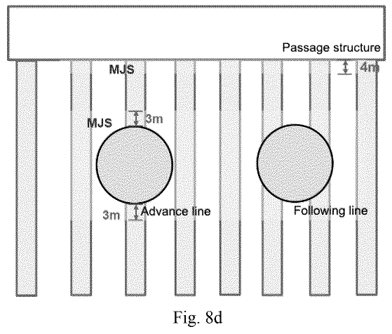

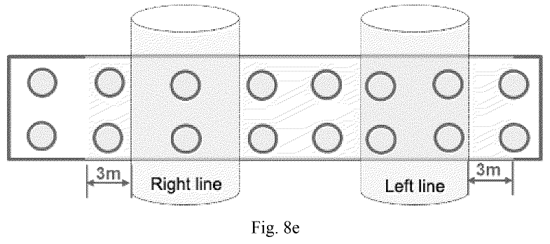

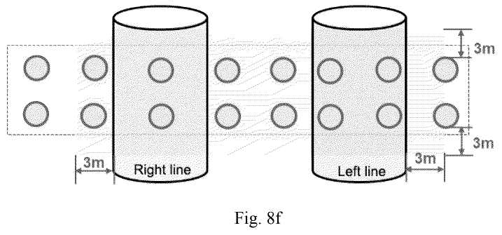

Reinforcement Scheme 2: The protective effects of different soil mass reinforcement thicknesses under the passage on the existing structure are compared to further investigate the reasonable reinforcement thickness. With the soil mass reinforcement above and below the tunnel maintained at 3 m and the horizontal reinforcement range in the pile grinding area maintained at 3 m outside the engineering piles, as shown in FIGS. 8e-f, four reinforcement schemes are implemented by reinforcing the soil mass within ranges of 1 m (Scheme 2a), 2 m (Scheme 2b), 3 m (Scheme 2c), and 4 m (Scheme 2d) below the underground passage, respectively, as shown in FIGS. 8a-d (only part of the pile foundations within the reinforcement area are illustrated).

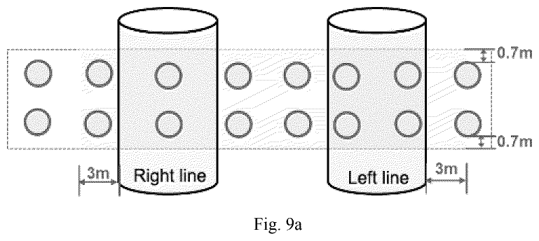

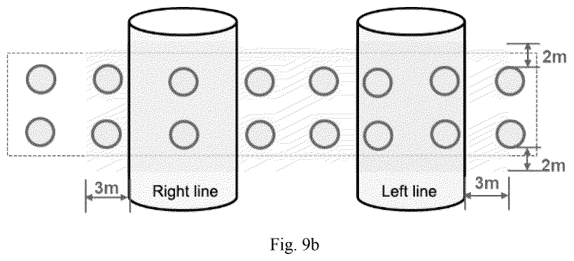

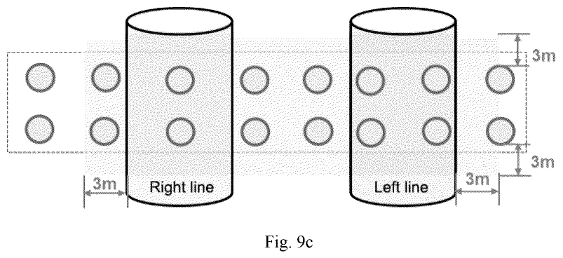

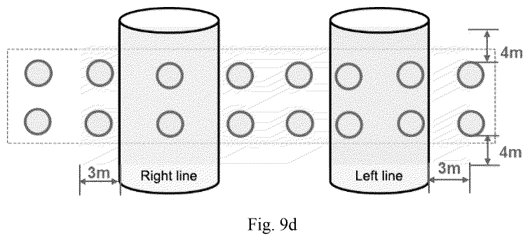

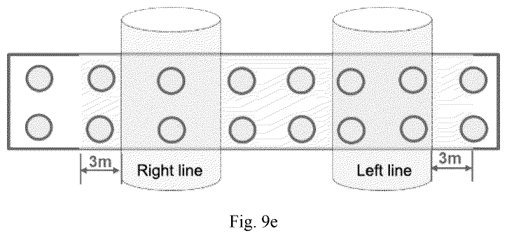

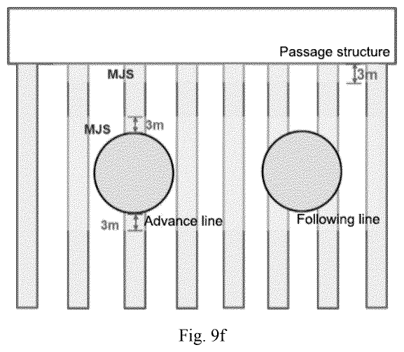

Reinforcement Scheme 3: The protective effects of different longitudinal soil mass reinforcement thicknesses in the pile grinding area on the existing structure are compared to further investigate the reasonable reinforcement thickness. With the soil mass reinforcement below the passage maintained at 3 m and the soil mass reinforcement above and below the tunnel maintained at 3 m, as shown in FIGS. 9e-f, four reinforcement schemes are implemented by reinforcing the soil mass within ranges of 0.7 m (Scheme 3a), 2 m (Scheme 3b), 3 m (Scheme 3c), and 4 m (Scheme 3d) outside the engineering piles, respectively, as shown in FIGS. 9a-d (only part of the pile foundations within the reinforcement area are illustrated).

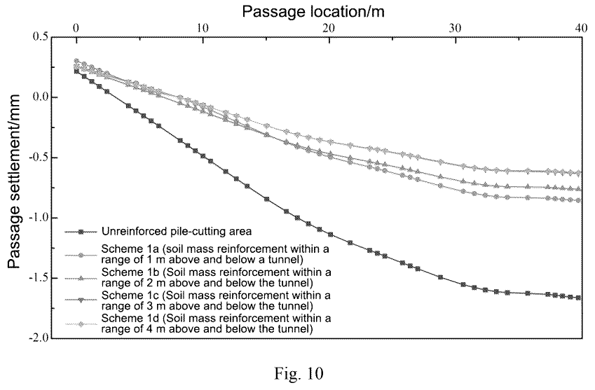

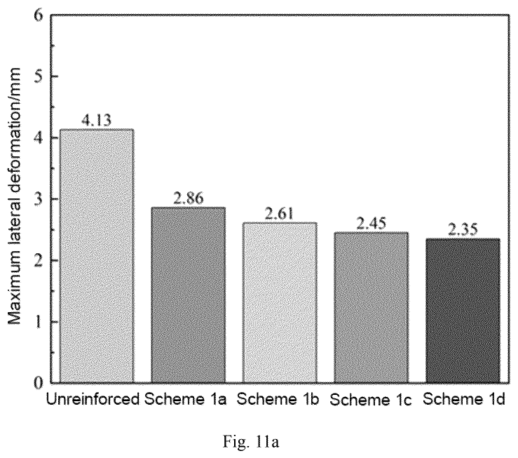

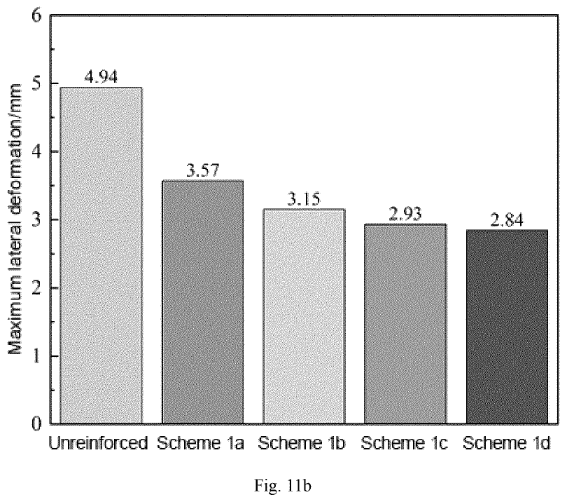

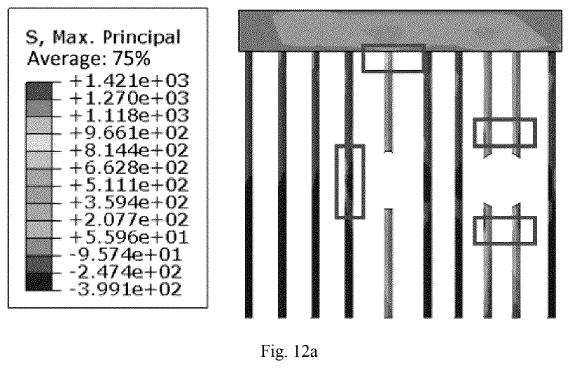

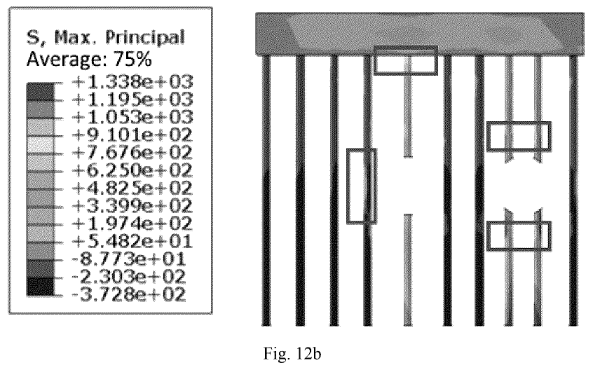

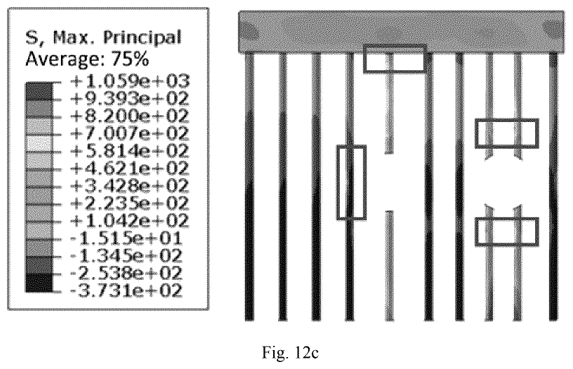

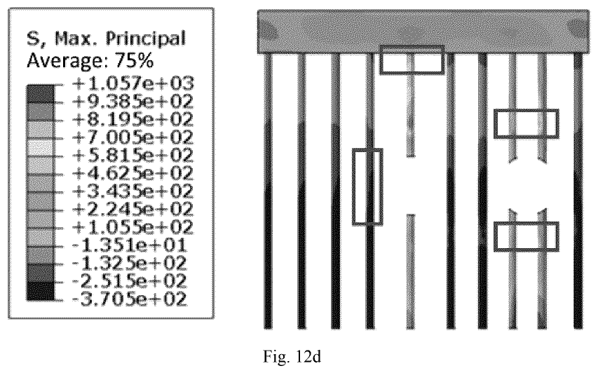

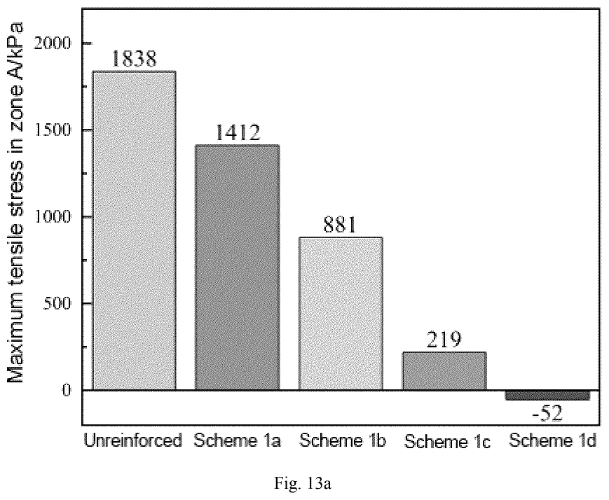

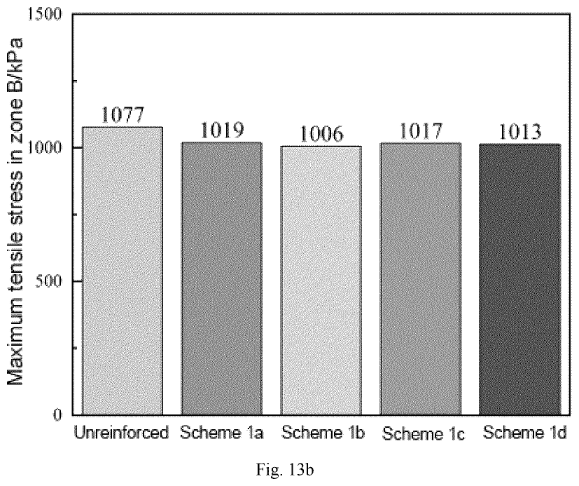

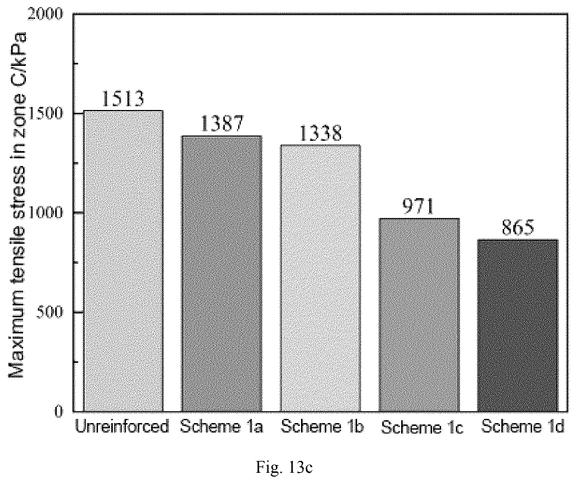

The reinforced soil material adopts an elastic constitutive model. Response curves of different reinforcement schemes for controlling settlement of the underground passage and improving pile foundation deformation and stress characteristics are obtained by using the ABAQUS finite element software, as shown in FIGS. 10, 11a-b and 12a-b. The smaller the settlement, i.e., the closer the curve is to the upper portion, the better the effect of controlling the settlement of the underground passage. Referring to FIGS. 11a-b, the smaller the deformation, i.e., the lower the position of the histogram, the better the improvement of pile foundation deformation. Referring to FIGS. 12a-d, the smaller the maximum tensile and compressive stresses of the pile foundations, i.e., the smaller the values corresponding to the boxed areas in the figures, the better the improvement of the stress characteristics of the pile foundations. Furthermore, the maximum tensile stresses in the pile foundations after shield tunnel construction in various tensile stress zones under different reinforcement schemes are extracted for analysis, where zone A refers to a side of adjacent piles of obstacle pile that is far from the tunnel, zone B refers to a joint between the residual pile above the cut pile foundation of the right line and the passage, and zone C refers to a position of the residual pile of the cut pile foundation of the left line that is close to the tunnel position. Histograms are plotted as shown in FIGS. 13a-c. The smaller the maximum tensile stress, i.e., the lower the position of the histogram, the better the reinforcement effect. The reasonable reinforcement range is determined by comprehensively considering the improvement effect of the above reinforcement schemes on the settlement of the existing structure, the suppression effect on the horizontal displacement of the pile foundations, and the improvement effect on the stress of the pile foundations, thereby evaluating the protective effect of the stratum reinforcement.

### Embodiment 2

An analysis process of step (S8) for a shield tunneling section directly crossing pile foundations in Shaoxing Metro is further investigated below. The stratum reinforcement for the shield tunnel crossing the existing structure is modeled and analyzed by using the ABAQUS finite element software. The specific details are described as follows.

Analysis results show that different vertical reinforcement thicknesses in the soil mass of the pile grinding area can effectively reduce the overall passage settlement, inhibit horizontal deformation of the pile foundations, and improve the stress condition of the pile foundations. As shown in FIG. 10, compared to the unreinforced scenario in the pile grinding area, different reinforcement thicknesses can reduce the maximum passage settlement value by more than 48%. As shown in FIGS. 11a-b, horizontal deformation of the pile foundations is inhibited by more than 28%. When the reinforcement thickness exceeds 3 m, the settlement of the passage structure and the horizontal displacement of the pile foundations no longer show significant reduction. As shown in FIGS. 12a-d, as the reinforcement thickness above and below the tunnel increases, the maximum tensile and compressive stresses in the pile foundations decrease, but the reduction effect is not significant, and the incremental benefit of additional reinforcement gradually weakens. After the reinforcement thickness above and below the tunnel reaches 3 m, further reinforcement shows almost no significant change in the improvement of the maximum principal stress in the pile foundations. In order to further analyze the influence of stratum reinforcement on the stress state of the pile foundations, as shown in FIGS. 13a-c, compared to the unreinforced scenario in the pile grinding area, the schemes varying in reinforcement thickness reduce the maximum principal stress in zone A by more than 23%. When the reinforcement thickness above and below the tunnel reaches 4 m, tensile stress no longer appears in zone A. The tensile stress in zone B exhibits no significant change under the schemes varying in reinforcement thickness. Under the schemes varying in reinforcement thickness, the maximum tensile stress in zone C is reduced by more than 8.3%. Reinforcement of the soil mass around the tunnel can improve the lateral tensile stress condition of the adjacent piles of the obstacle pile and the tensile stress condition at the bottom of the residual pile, but has no significant effect on the stress condition of the pile foundation at the joint between the residual pile and the passage. Comprehensively considering the improvement effect of the reinforcement schemes on the settlement of the existing structure, the inhibitory effect on the horizontal displacement of the pile foundations, and the improvement effect on the stress of the pile foundations, the protective effectiveness of different reinforcement thicknesses on the existing structure is ranked as Scheme 1d>Scheme 1c>Scheme 1b>Scheme 1a.

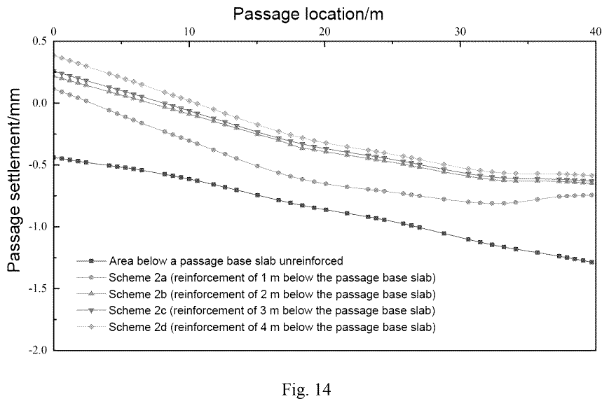

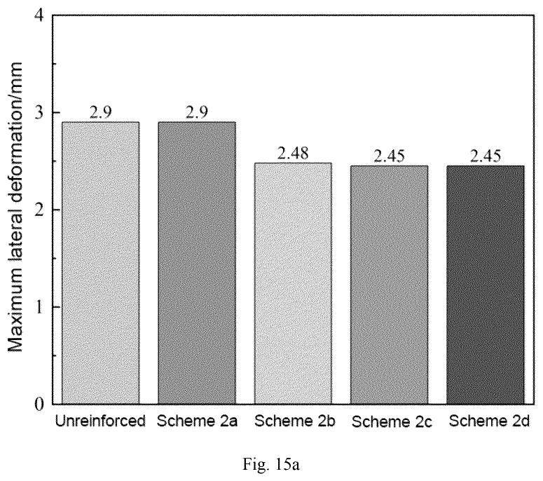

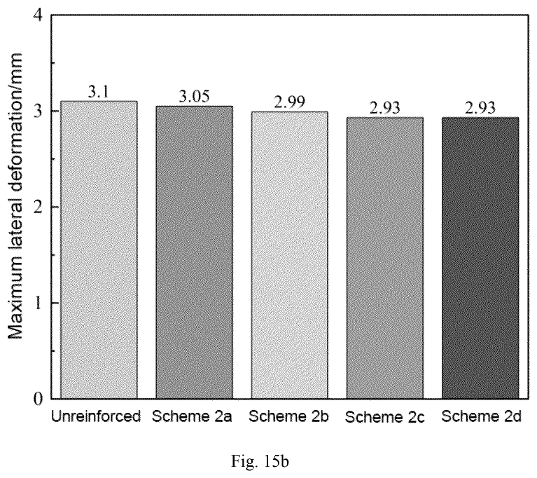

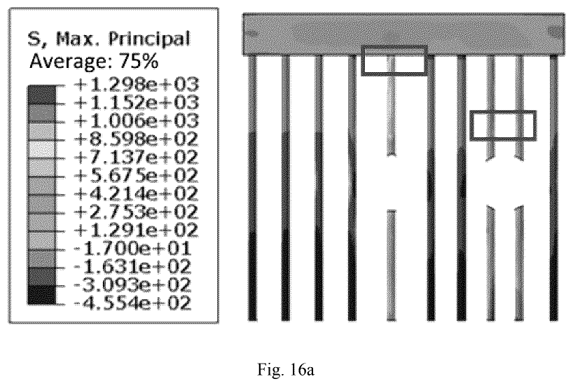

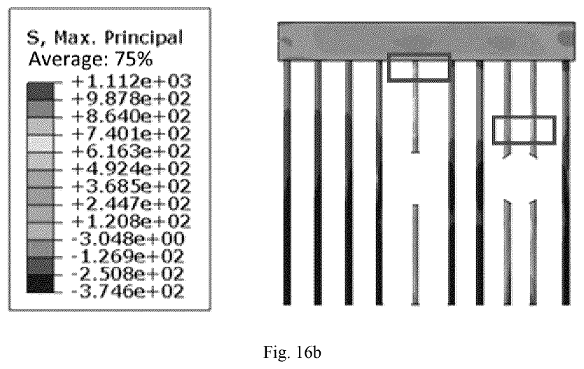

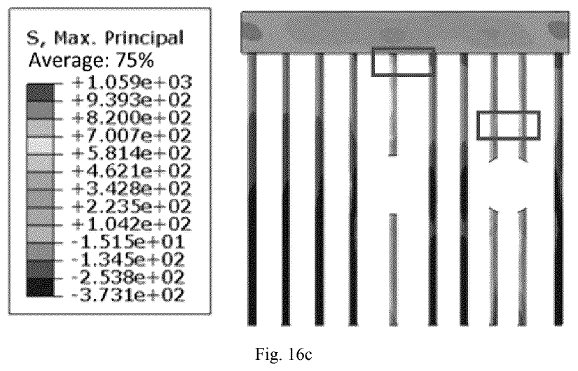

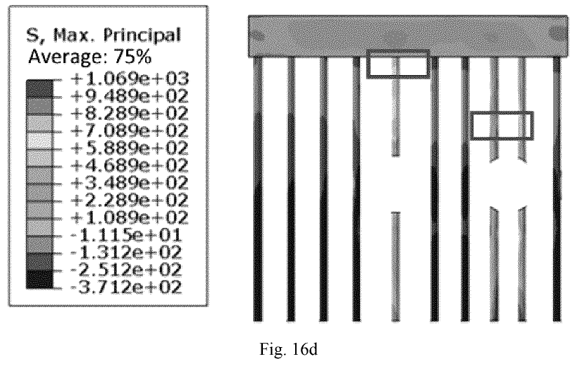

Analysis results show that that different reinforcement thicknesses in the soil mass below the passage base slab can effectively reduce the overall passage settlement and improve the stress condition of the pile foundations, but have no obvious effect on the horizontal displacement of the pile foundations. As shown in FIG. 14, compared to the unreinforced scenario below the passage, the schemes varying in reinforcement thickness can reduce the maximum passage settlement value by more than 38%. The settlement of the passage structure decreases as the reinforcement thickness increases, but the degree of reduction gradually weakens. As shown in FIGS. 15a-b, compared to the unreinforced scenario below the passage base slab, the reduction in pile body displacement after reinforcement is relatively small, and different reinforcement thicknesses below the passage base slab have no significant difference in the effect on pile body displacement. As shown in FIGS. 16a-d, as the thickness of soil mass reinforcement below the passage base slab increases, the tensile stress in the residual pile can be reduced, the risk of tensile cracking in the passage structure is lowered, and an excellent protective effect is achieved for the upper structure. Comprehensively considering the improvement effect of the schemes varying in reinforcement thickness on the settlement of the existing structure, the inhibitory effect on the horizontal displacement of the pile foundations, and the improvement effect on the stress of the pile foundations, the four reinforcement schemes are ranked as Scheme 2c≈Scheme 2d>Scheme 2b>Scheme 2a.

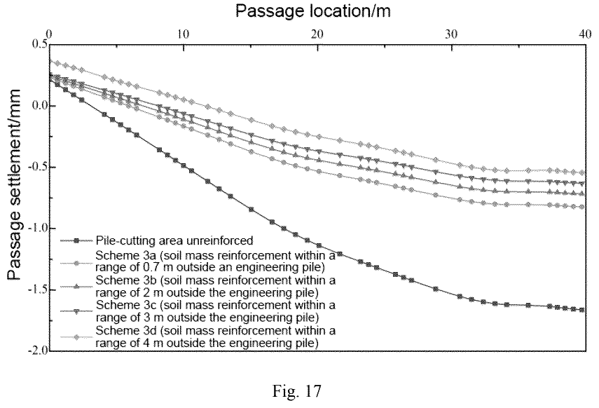

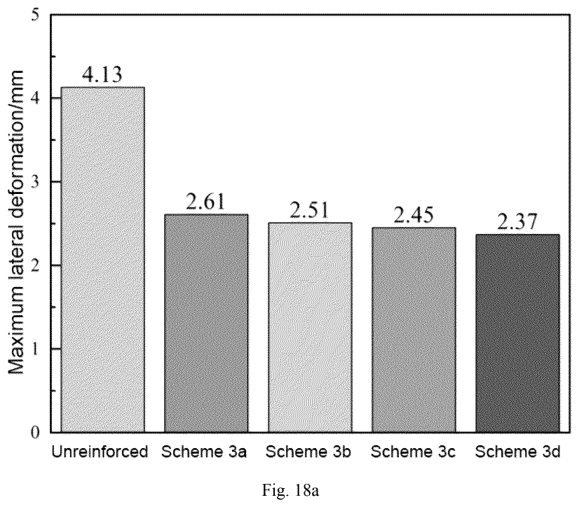

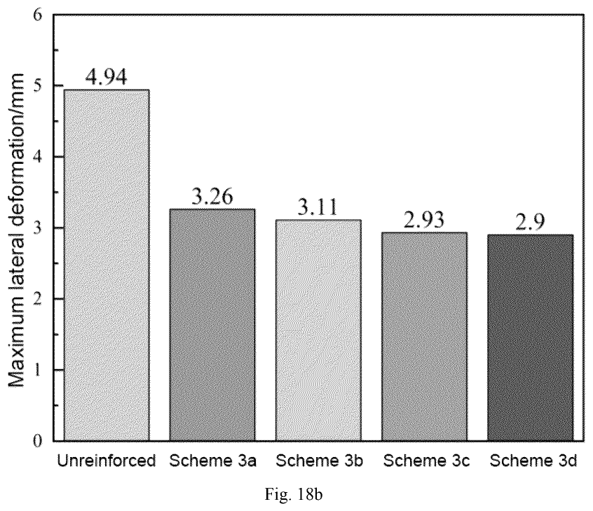

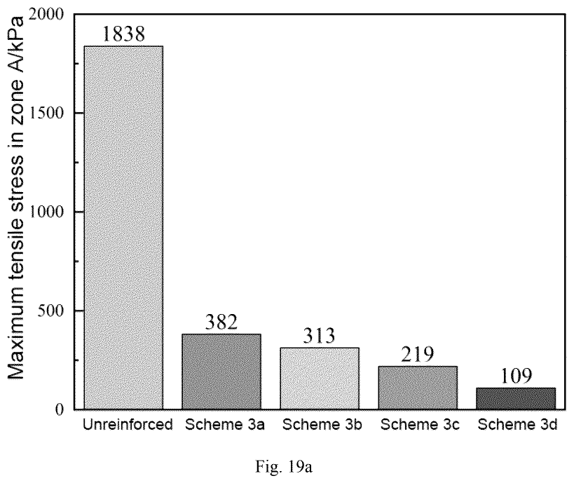

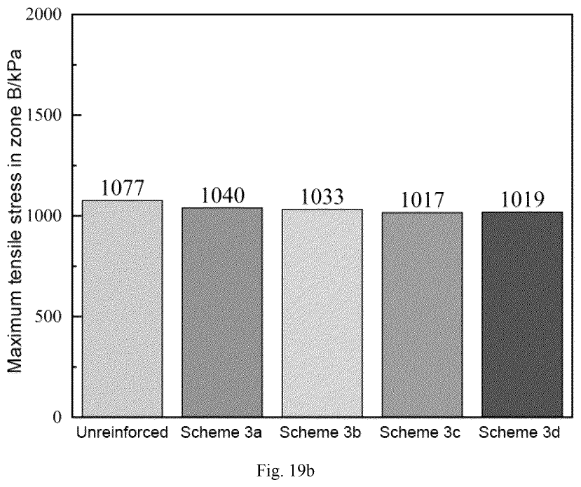

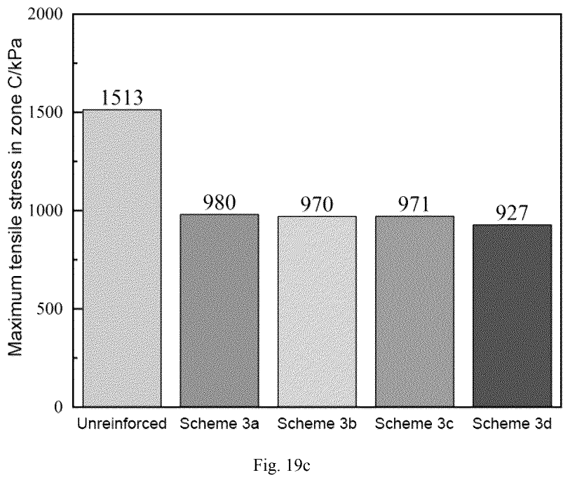

The overall passage settlement and the horizontal deformation of the pile foundations both decrease as the longitudinal reinforcement thickness in the soil mass of the pile grinding area increases, but the incremental degree of reduction gradually decreases. As shown in FIG. 17, compared to the unreinforced scenario around the tunnel, the schemes varying in reinforcement thickness can reduce the maximum passage settlement value by more than 31%. As shown in FIGS. 18a-b, compared to the unreinforced scenario around the tunnel, horizontal deformation of the pile foundations is inhibited by more than 34%. As shown in FIGS. 19a-c, under the schemes varying in reinforcement thickness, the maximum principal stress in zone A is reduced by more than 79%. When the reinforcement thickness above and below the tunnel reaches 4 m, tensile stress no longer appears in zone A. The tensile stress in zone B has no obvious change under these schemes. The implementation of stratum reinforcement can effectively reduce the tensile stress in the residual pile in zone C, but the maximum tensile stress value has no obvious change under these schemes. Therefore, the implementation of longitudinal reinforcement in the soil mass around the tunnel can improve the lateral tensile condition of the neighboring piles of the obstacle pile and the tensile condition near the tunnel in the residual pile, but has no significant effect on the stress of the pile foundation at the joint between the residual pile and the passage. Comprehensively considering the improvement effect of these schemes on the settlement of the existing structure, the inhibitory effect on the horizontal displacement of the pile foundations, and the improvement effect on the stress of the pile foundations, the four reinforcement schemes are ranked as Scheme 3d≈Scheme 3c>Scheme 3b>Scheme 3a.

By comparing the protective effects of different reinforcement areas on the deformation and stress of the existing structure, and considering the economic efficiency of grouting reinforcement, the reasonable reinforcement range for the stratum below the passage and in the pile grinding area are finally determined, that is, a reinforcement thickness of 3 m for the soil mass below the passage, a vertical reinforcement range of the soil mass in the pile grinding area of 3 m above and below the tunnel, and a longitudinal reinforcement range of 3 m outside the engineering piles.

The embodiments described above are merely illustrative of the present application, and are not intended to limit the scope of the present application. Any modifications or equivalent substitutions made based on essence and principles of the present application shall fall within the scope of the disclosure defined by the appended claims.

What is claimed is:

1. A stratum reinforcement modeling and analysis method for a shield tunnel crossing an existing structure, comprising:
(S1) acquiring geological information and an engineering structure condition of the existing structure through geological survey, and determining physical parameters of different soil mass layers based on a laboratory test;
(S2) constructing a three-dimensional (3D) model, performing mesh generation on the 3D model, and defining a constraint for the 3D model, wherein the 3D model comprises an overall stratum model of a shield tunneling area and an internal model combining an existing structure model with a shield tunnel model;
(S3) selecting model parameters for the 3D model;
(S4) selecting a soil mass constitutive model for the 3D model;
(S5) performing synchronous grouting simulation on the 3D model;
(S6) performing simulation of a construction load on the 3D model;
(S7) performing simulation of a shield tunneling construction process on the 3D model; and
(S8) changing stratum parameters to achieve stratum reinforcement modeling of a process of the shield tunnel crossing the existing structure, and performing data analysis by adopting different reinforcement schemes to achieve stratum reinforcement modeling and numerical analysis of the process of the shield tunnel crossing the existing structure.

2. The stratum reinforcement modeling and analysis method of claim 1, wherein step (S1) is performed through steps of:
(S11) performing stratum thickness division based on a geological prospecting borehole coring condition and engineering information of the existing structure, and acquiring stratum distribution information and an internal structure condition of a construction area; and
(S12) acquiring the physical parameters through the laboratory test, and simulating mechanical behavior of a soil mass in the construction area; wherein the physical parameters comprise unit weight, water content, void ratio, cohesion, internal friction angle and elastic modulus of the soil mass.

3. The stratum reinforcement modeling and analysis method of claim 1, wherein step (S2) is performed through steps of:
(S21) constructing and generating the overall stratum model based on the geological information and the engineering structure condition, and performing stratum boundary division and naming;
(S22) constructing the existing structure model based on actual design drawing dimensions;
(S23) constructing the shield tunnel model, wherein the shield tunnel model comprises a segment lining, a grouting layer and a shield shell; and constructing the 3D model by integrating the overall stratum model, the existing structure model and the shield tunnel model according to an actual construction scheme; and
(S24) performing mesh generation on the 3D model, wherein each of a soil mass, the segment lining, the grouting layer, the existing structure and the shield shell adopts an eight-node hexahedral mesh element; and
defining the constraint for the 3D model, wherein a bottom of the 3D model adopts a vertical constraint, a periphery of the 3D model adopts a horizontal constraint, and a top of the 3D model is a free boundary.

4. The stratum reinforcement modeling and analysis method of claim 1, wherein step (S3) is performed through steps of:
according to an influence of a lining joint on stiffness of a lining structure, reducing a stiffness of a segment lining with a stiffness reduction coefficient of 0.6; and determining values of physical and mechanical parameters of a grouting layer, a shield shell, the segment lining, an underground passage and the existing structure based on the geological information and the engineering structure condition; wherein the physical and mechanical parameters comprise density, elastic modulus and Poisson's ratio.

5. The stratum reinforcement modeling and analysis method of claim 1, wherein step (S4) is performed through steps of:
selecting a Modified Cam-Clay model as the soil mass constitutive model based on the geological information and the engineering structure condition, wherein the Modified Cam-Clay model is expressed as:
$${( \frac{t}{{M}_{a}} )}^{2} + \frac{1}{{β}^{2}} {( \frac{P}{a} - 1 )}^{2} = 1 ,$$
wherein M is a slope of a critical state line (CSL) on a P−t plane, and is called a critical state stress ratio, α is a value of P corresponding to an intersection point between an ellipse and the CSL, β is a parameter controlling a shape of a yield surface, a value of β is equal to 1 on a first side where P<α, and is free of being restricted to 1 on a second side where P>α, the value of β serves to affect the shape of the yield surface on a corresponding one of the first side and the second side, t is a generalized shear stress, and P is an effective mean principal stress;
assigning values to parameters of a soil mass of the Modified Cam-Clay model based on the geological information and the engineering structure conditions, wherein the parameters of the soil mass comprises density, critical state stress ratio, slope of a normal consolidation curve, slope of a rebound curve, Poisson's ratio and at-rest earth pressure coefficient of the soil mass.

6. The stratum reinforcement modeling and analysis method of claim 1, wherein step (S5) is performed through steps of:
generalizing grouting as an equivalent layer that is homogeneous, equal-thickness and elastic based on the geological information and the engineering structure condition, wherein a thickness δ of the equivalent layer is calculated through the following equation:
$$δ = ηΔ ,$$
wherein Δ is a theoretical value of a shield tail void, and η is a reduction coefficient ranging from 0.7 to 2.0.

7. The stratum reinforcement modeling and analysis method of claim 1, wherein the construction load comprises a tunneling face support pressure and a shield tail grouting pressure; and
step (S6) is performed through steps of:
determining the tunneling face support pressure according to an actual tunneling face support pressure recorded during shield tunneling in an actual project; determining the shield tail grouting pressure by back-calculation of an actual shield tail grouting pressure from an instrument-recorded grouting pressure through the following equation:
$${P}_{g} = {P}_{g 0} - Δ {P}_{1} - Δ {P}_{2} - Δ {P}_{3} ,$$
wherein P₈ is the instrument-recorded grouting pressure, P_{g0} is the actual shield tail grouting pressure, ΔP₁ is a frictional pressure loss, ΔP₂ is a local pressure loss, and ΔP₃ is a grouting pressure loss during vertical distribution expansion; and ΔP₁, ΔP₂ and ΔP₃ are determined based on hydrodynamic calculation.

8. The stratum reinforcement modeling and analysis method of claim 1, wherein step (S7) is performed through steps of:
performing step-by-step tunneling simulation on the shield tunneling construction process using an element birth and death method provided by an ABAQUS software, and discretizing a continuous steady-state process of shield tunneling construction into a stepwise steady-state tunneling process with a length of one tunneling step equal to a distance of three lining rings in the shield tunnel model; wherein each tunneling step comprises a shield tunneling step, the process of the shield tunnel crossing the existing structure and a shield tail detachment process; and
during the shield tunneling step, killing a corresponding soil mass element, and simultaneously activating a segment lining, a grouting, a preset shield shell element and a load condition at a corresponding position; during simulation of the process of the shield tunnel crossing the existing structure, killing a conflicting part of the existing structure that the shield tunnel crosses by using the element birth and death method, and activating the preset shield shell element; and after a shield tail is detached, killing the preset shield shell element, and activating a preset shield shell element grouting layer, a segment lining layer and a corresponding grouting pressure.

9. The stratum reinforcement modeling and analysis method of claim 1, wherein step (S8) is performed through steps of:
simulating reinforcement measures by changing parameters relevant to a stratum material based on the 3D model, constructing a stratum reinforcement numerical model using an ABAQUS finite element software; and adopting an elastic constitutive model for a reinforced soil material, wherein parameters of the reinforced soil material comprises density, Poisson's ratio and elastic modulus of a soil mass; and
acquiring response curves of different reinforcement schemes for controlling settlement of an underground passage and improving deformation and stress characteristics of the existing structure using the Abaqus finite element software, determining a reasonable reinforcement range, and evaluating a stratum reinforcement protection effect.
